(19) United States
(12) Patent Application Publication
(10) Pub. No.: US 2025/0033087 A1
(43) Pub. Date: Jan. 30, 2025

(54) Article Transport Facility

(71) Applicant: Daifuku Co., Ltd., Osaka-shi (JP)

(72) Inventors: Kengo Ikedo, Komaki-shi (JP); Hiroshi Hayakawa, Komaki-shi (JP)

(21) Appl. No.: 18/782,619

(22) Filed: Jul. 24, 2024

(30) Foreign Application Priority Data
Jul. 25, 2023 (JP) 2023-120713

(51) Int. Cl. B07C 3/08

(52) U.S. Cl. CPC B07C 3/08

(57) ABSTRACT

An article transport facility includes an article transport vehicle and a control system that controls the article transport vehicle. The article transport facility includes a plurality of receiving conveyors each to be a destination of an article. The plurality of receiving conveyors can hold less than or equal to a maximum holdable-article number of articles. The control system calculates, for each of the plurality of receiving conveyors, a receivable-article number by subtracting a held-article number and a reserved-article number from the maximum holdable-article number, and selects a receiving conveyor to be the destination of the article based on the receivable-article number of each of the plurality of receiving conveyors.

### CROSS-REFERENCE TO RELATED APPLICATION

This application claims priority to Japanese Patent Application No. 2023-120713 filed Jul. 25, 2023, the disclosure of which is hereby incorporated by reference in its entirety.

### BACKGROUND OF THE INVENTION

### Field of the Invention

The present invention relates to an article transport facility.

### Description of Related Art

Known article transport facilities include transport vehicles that move along a transport path to transport articles and a control system that controls the transport vehicles. An example of such article transport facilities is described in Japanese Unexamined Patent Application Publication No. 2021-76970 (Patent Literature 1).

In the article transport facility in Patent Literature 1, a controller (controller H) sets a setting path (setting path 1A) for causing an article transport vehicle (article transport vehicle 3) to travel to a destination on the transport path (travelable path 1) including multiple links (links L) based on a link cost set for each link. In Patent Literature 1, the link cost is set higher for a longer time taken for the article transport vehicle to pass through the link, and is adjusted to be higher for a greater number of other vehicles scheduled to pass through the link. The controller calculates, for multiple candidate paths (candidate paths 1B), a path cost from the sum of link costs and node costs for each candidate path and determines a candidate path with a minimum path cost as the setting path.

In Patent Literature 1, a destination is first determined, and the cost is calculated based on the state of the transport path alone to determine the setting path to the destination. However, for example, similar cost calculation may be used to determine a specific destination among multiple destination candidates. In this case, when the destination candidates can each hold multiple articles at the same time, the states of the destinations may also greatly affect the article transport efficiency of the entire article transport facility. For example, the cost of the path to a specific destination candidate may be low but the destination candidate may already hold as many articles as the maximum number of holdable articles. In this case, waiting time can lower the total transport efficiency, despite the short time to reach the destination candidate.

### SUMMARY OF THE INVENTION

One or more aspects are directed to an article transport facility with the article transport efficiency less likely to decrease in the entire facility.

An article transport facility according to an aspect of the disclosure includes an article transport vehicle that moves along a transport path to transport an article, a control system that controls the article transport vehicle, and a plurality of receiving conveyors each to be a destination of the article transported by the article transport vehicle. Each of the plurality of receiving conveyors can hold less than or equal to a predetermined maximum holdable-article number of articles. The control system calculates, for each of the plurality of receiving conveyors, a receivable-article number by subtracting a held-article number and a reserved-article number from the maximum holdable-article number. The held-article number is a number of articles held by each of the plurality of receiving conveyors. The reserved-article number is a number of articles determined to be transported to each of the plurality of receiving conveyors. The control system selects, among the plurality of receiving conveyors, a receiving conveyor to be the destination of the article based on the receivable-article number of each of the plurality of receiving conveyors.

In this structure, the receiving conveyor to be the destination of the article is selected based on the receivable-article number (in other words, a margin to the maximum holdable-article number based on the sum of the actual held-article number and the reserved-article number) calculated for each of the plurality of receiving conveyors. This reduces the likelihood that the article transport vehicle reaches the receiving conveyor to be the destination but is to wait until the receiving conveyor is ready to actually receive the article. The article transport facility thus has the article transport efficiency less likely to decrease in the entire facility.

Further features and advantageous effects of the technique according to one or more embodiments of the disclosure will be apparent from exemplary and nonlimiting embodiments described below with reference to the drawings.

### BRIEF DESCRIPTION OF THE DRAWINGS

FIG. 1 is a schematic diagram of an article transport facility according to an embodiment.

FIG. 2 is a perspective view of an article transport vehicle.

FIG. 3 is a block diagram of a control system.

FIG. 4 is a schematic diagram of receiving conveyors.

FIG. 5 is a diagram describing a method for calculating a receiving cost.

FIG. 6 is a flowchart of destination determination control.

FIG. 7 is a schematic diagram of an article transport facility according to another embodiment.

### DESCRIPTION OF THE INVENTION

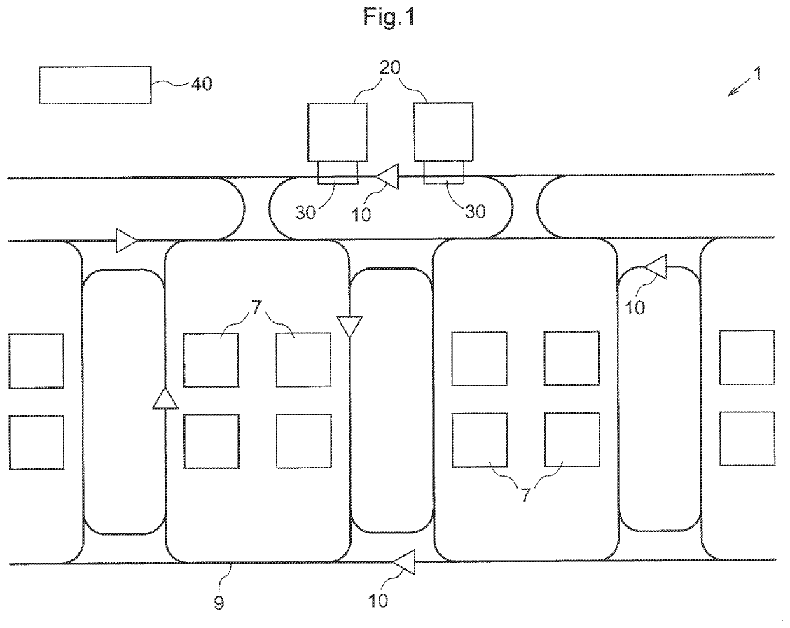

An article transport facility according to an embodiment will be described with reference to the drawings. An article transport facility 1 according to the present embodiment is used for transporting articles A in, for example, a semiconductor fabrication plant. As shown in FIG. 1, the article transport facility 1 includes one or more article transport vehicles 10, one or more storage units 20, one or more transfer units 30, and a control system 40. The article transport facility 1 according to the present embodiment includes multiple article transport vehicles 10, multiple storage units 20, the transfer units 30 for the respective storage units 20, and the control system 40.

The article transport vehicles 10 move along a transport path 9 to transport the articles A. The articles A are, for example, front opening unified pods (FOUPs) that contain semiconductor wafers. In the present embodiment, the transport path 9 of the article transport vehicles 10 is a physical path including a pair of travel rails 91 hung from the ceiling. In other words, the article transport vehicles 10 in the present embodiment are ceiling-hung transport vehicles that move along the travel rails 91 hung from the ceiling.

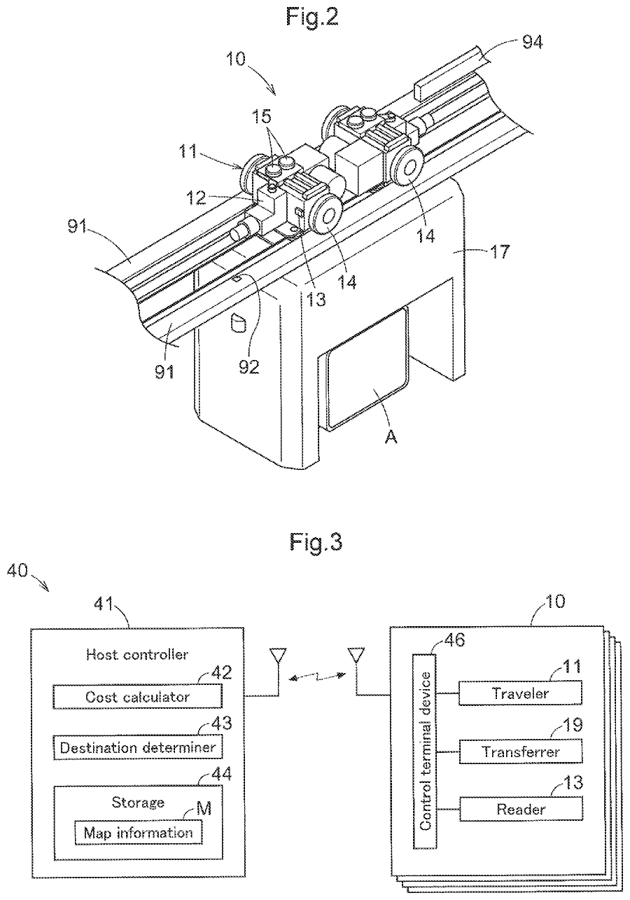

As shown in FIG. 2, each transport vehicle 10 includes a traveler 11, a body 17, and a transferrer 19 (refer to FIG. 3). The traveler 11 travels on the pair of travel rails 91. The traveler 11 includes a vehicle body 12 and multiple wheels 14 supported by the vehicle body 12. The wheels 14 roll on travel surfaces (upper surfaces in this example) of the travel rails 91. At least one of the multiple wheels 14 is a drive wheel drivably connected to a drive source (e.g., an electric motor such as a servo motor).

A reader 13 is disposed on the vehicle body 12. The reader 13 reads position information held by position information holders 92 on the travel rails 91. Each position information holder 92 is, for example, a one-dimensional code (barcode), a two-dimensional code (e.g., quick response or QR code), or a radio-frequency identification tag. The position information holders 92 are disposed at multiple positions and each hold unique position information. The reader 13 is used as appropriate for the type of the position information holder 92. The reader 13 is, for example, a bar code reader, a QR code reader, or a radio-frequency identification tag reader.

The vehicle body 12 supports guide wheels 15 to allow movement in a width direction (direction perpendicular to a direction, or a travel direction, in which the travel rails 91 extend). The guide wheels 15 come in contact with guide rails 94 each disposed upward from the travel rails 91 in a branch or a junction on the transport path 9 to guide branching or merging.

The body 17 is hung from the traveler 11 and contains the transferrer 19 in its internal space. The transferrer 19 is switchable between a holding orientation and a releasing orientation and can be lifted and lowered. When the transferrer 19 in the holding orientation is at a lifted position, the body 17 holds an article A in its internal space. The transferrer 19 is lowered to a predetermined position and switched to the holding orientation or the releasing orientation, and can thus transfer an article A.

The storage units 20 store the articles A transported by the article transport vehicles 10. The storage units 20 in the present embodiment each include a multilayer storage shelf 21 including a storage shelf, a lifter, and a transfer device. The storage shelf is a tower with multiple layers each including a compartment. The lifter moves up and down along a post extending through the layers. The transfer device is disposed in the lifter and transfers an article A to or from one of the compartments.

The transfer units 30 transfer the articles A between the article transport vehicles 10 and the storage units 20. As shown in FIG. 4, each transfer unit 30 includes a receiving conveyor 31 and a transfer conveyor 38. The receiving conveyor 31 receives an article A from an article transport vehicle 10 and transfers the article A to the corresponding storage unit 20. The receiving conveyor 31 may thus be a direct destination of the article A transported by the article transport vehicle 10. The transfer conveyor 38 receives an article A from the corresponding storage unit 20 and transfers the article A to an article transport vehicle 10. The transfer conveyor 38 may thus be a direct source of the article A transported by the article transport vehicle 10.

The transfer units 30 are individually disposed for the respective storage units 20 on a one-to-one basis. In other words, a set of one receiving conveyor 31 and one transfer conveyor 38 is disposed for one storage unit 20 (multilayer storage shelf 21 in this example). The multiple receiving conveyors 31 receive articles A from article transport vehicles 10 and transfer the articles A to the respective storage units 20, and are functionally equivalent to one another. The multiple transfer conveyors 38 receive articles A from the respective storage units 20 and transfer the articles A to article transport vehicles 10, and are functionally equivalent to one another.

The receiving conveyors 31 are elongated to hold multiple articles A at the same time. Each receiving conveyor 31 includes a receiving area 32 to receive an article A from an article transport vehicle 10 and a transfer area 36 to transfer the received article A to the corresponding storage unit 20. In the present embodiment, the storage units 20 (the multilayer storage shelves 21 in this example) each correspond to a device other than an article transport vehicle. In the present embodiment, each receiving conveyor 31 further includes one or more waiting areas 34 between the receiving area 32 and the transfer area 36. In the present embodiment, each receiving conveyor 31 includes one receiving area 32, multiple (three in the example in FIG. 4) waiting areas 34, and one transfer area 36.

Each receiving conveyor 31 can hold less than or equal to a maximum holdable-article number Nx of articles A. The maximum holdable-article number Nx is herein a value determined by the total number of receiving area 32, waiting areas 34, and transfer area 36. The value is 5 (=1+3+1) in this example. The waiting areas 34 may be eliminated. The receiving area 32 and the transfer area 36 may be used in a shared manner. Thus, the maximum holdable-article number Nx is an integer greater than or equal to 1. Each receiving conveyor 31 may include the receiving area 32 and the transfer area 36 separately and may include the waiting areas 34 that are not too many areas. The maximum holdable-article number Nx may be about three to five.

The transfer conveyors 38 are also elongated to hold multiple articles A at the same time. Although not explicitly shown in FIG. 4 in a particularly distinguishable manner, each transfer conveyor 38 includes a receiving area to receive an article A from the corresponding storage unit 20, a transfer area to transfer the received article A to an article transport vehicle 10, and waiting areas between the receiving area and the transfer area as well. The number of articles A holdable by the transfer conveyor 38 may be the same as the maximum holdable-article number Nx of the receiving conveyor 31.

The receiving conveyors 31 and the transfer conveyors 38 may each be, for example, roller conveyors, belt conveyors, or slat conveyors. The receiving conveyors 31 and the transfer conveyors 38 may be the same type of conveyors or different types of conveyors.

As shown in FIG. 1, the article transport facility 1 according to the present embodiment also includes multiple processing devices 7. When the articles A are, for example, FOUPs that contain semiconductor wafers as described above, the processing devices 7 may be, for example, processing apparatuses that perform processing on the semiconductor wafers. Support tables on which the articles A are transferred are disposed adjacent to the respective processing devices 7. The article transport vehicles 10 also transfer or receive the articles A to or from the processing devices 7.

Conveyors may be used in place of the support tables described above. The conveyors transfer the articles A to or from the article transport vehicles 10, similarly to the receiving conveyors 31. However, the conveyors receive the articles A from the article transport vehicles 10 and transfer them to the respective processing devices 7, which are different from the devices to which the receiving conveyors 31 transfer the articles A. Thus, in the present embodiment, the conveyors are not functionally equivalent to the receiving conveyors 31.

The control system 40 controls the article transport vehicles 10. As shown in FIG. 3, the control system 40 in the present embodiment includes a host controller 41 disposed in the facility and control terminal devices 46 that are mounted on the respective article transport vehicles 10 and can communicate with the host controller 41. The host controller 41 and the control terminal devices 46 each include an arithmetic processor such as a central processing unit (CPU) and a main storage such as a random-access memory (RAM) or a read-only memory (ROM). The functions of the host controller 41 and the control terminal devices 46 are implemented by the arithmetic processor and a program executable on the arithmetic processor cooperating with each other.

The host controller 41 centrally controls the operations of the multiple article transport vehicles 10. The host controller 41 tracks, for example, the current position of each article transport vehicle 10 and the transport path (including a goal and waypoints) of each article transport vehicle 10, and controls the operations of the multiple article transport vehicles 10 based on such information. The host controller 41 also controls, for example, the operations of the receiving conveyors 31 and the transfer conveyors 38 and the operations of the lifters and the transfer devices included in the multilayer storage shelves 21 in the storage units 20.

The host controller 41 includes a cost calculator 42, a destination determiner 43, and a storage 44. The cost calculator 42 calculates a cost of transporting an article A by an article transport vehicle 10. The destination determiner 43 selects, among the multiple receiving conveyors 31, a receiving conveyor 31 to be a destination of the article A. The storage 44 prestores information about, for example, the structure of the transport path 9 and the attribute of each part of the transport path 9 as map information M.

In the present embodiment, an article A containing objects (e.g., semiconductor wafers) that have been processed in any of the processing devices 7 is transported to and stored in one of the multiple storage units 20. To determine the storage unit 20 to which the article A is transported (the receiving conveyor 31 to which the article A is transported), the cost calculator 42 and the destination determiner 43 cooperate with each other while referring to the map information M stored in the storage 44.

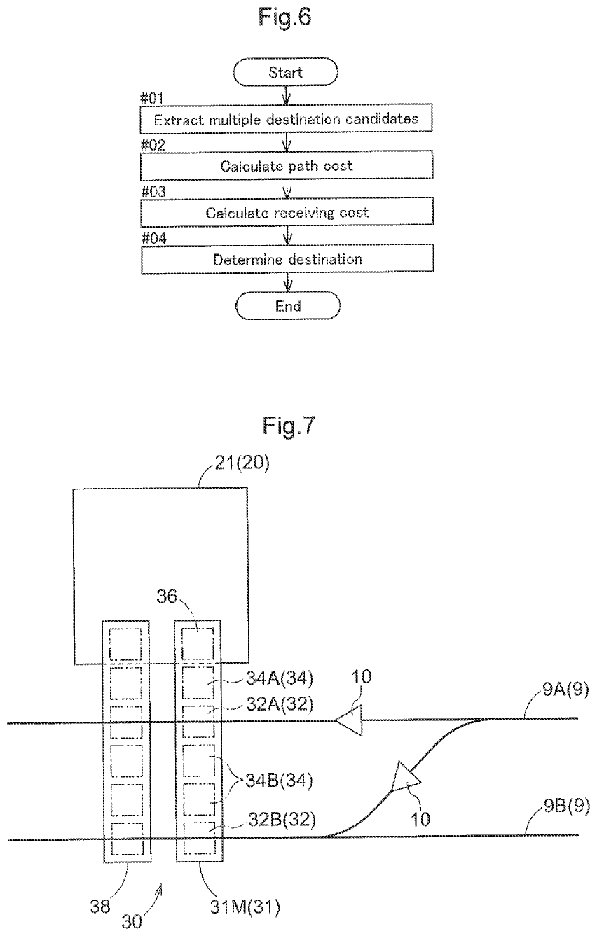

In response to determination that an article A is received from any of the processing devices 7 and transported to one of the storage units 20, the cost calculator 42 extracts multiple receiving conveyors 31 as destination candidates (step #01 in FIG. 6). Then, the cost calculator 42 first calculates a cost taken for the article transport vehicle 10 transporting the article A to move to each of the receiving conveyors 31 (hereafter referred to as candidate receiving conveyors) as the destination candidates (step #02 in FIG. 6). In the present embodiment, the cost taken for an article transport vehicle 10 to move to a candidate receiving conveyor is referred to as a path cost.

For example, the map information M includes information about multiple links and multiple nodes indicating a network structure of the transport path 9. Each link includes information about a cost (travel cost) that is based on, for example, its length and shape. Each node includes information about a cost (travel cost) that is based on, for example, the scale of merging or branching. The path cost is calculated as the sum of the costs of all the links and nodes included in the path from the current position of the article transport vehicle 10 to the position of the candidate receiving conveyor.

The cost of each link or each node is most susceptible to the cost that is based on the length of the link (the cost increases when the link is longer). The path cost thus typically increases in response to a longer travel distance of the article transport vehicle 10 to the candidate receiving conveyor. In other words, the path cost typically decreases in response to a shorter travel distance of the article transport vehicle 10 to the candidate receiving conveyor.

The path cost may be calculated based on other factors such as the number of areas at which the article transport vehicle 10 is to pause on the path to the candidate receiving conveyor or the likelihood of traffic congestion, in addition to the travel distance of the article transport vehicle 10 to the candidate receiving conveyor.

The cost calculator 42 then calculates a cost based on the current state of each of the candidate receiving conveyors, or more specifically, a cost based on the capacity to newly receive the article A (step #03 in FIG. 6). In the present embodiment, the cost based on the state of a candidate receiving conveyor is referred to as a receiving cost.

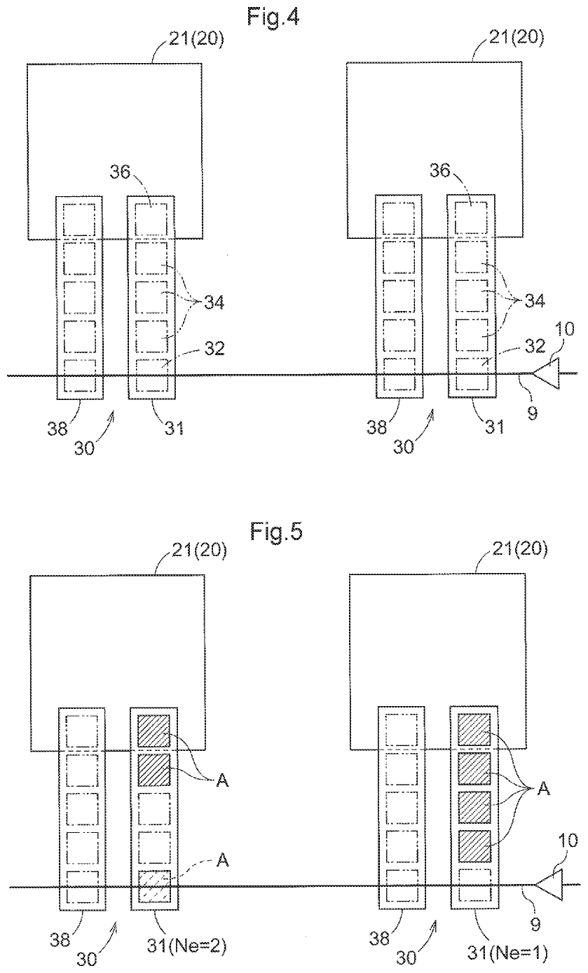

For example, in the example in FIG. 5 based on the example in FIG. 4, the two receiving conveyors 31 corresponding to the respective two storage units 20 are both extracted as candidate receiving conveyors. The maximum holdable-article numbers Nx of the two candidate receiving conveyors are both 5 as described above. The maximum holdable-article number Nx of each receiving conveyor 31 is predetermined based on its size (length) and tracked by the host controller 41. The cost calculator 42 obtains the predetermined maximum holdable-article number Nx of each candidate receiving conveyor.

The number of articles A (hereafter referred to as a held-article number Nf) currently held by a candidate receiving conveyor may be different for each candidate receiving conveyor. In the example in FIG. 5, the candidate receiving conveyor on the left holds two articles A, and the held-article number Nf is 2. In contrast, the candidate receiving conveyor on the right holds four articles A, and the held-article number Nf is 4. In FIG. 5, the articles A hatched with solid lines represent the articles A that are actually held.

The cost calculator 42 can obtain the held-article number Nf of each candidate receiving conveyor based on information such as the state of each article transport vehicle 10, the state of each receiving conveyor 31, and the states of the lifter and the transfer device included in each multilayer storage shelf 21 that are tracked by the host controller 41. A load sensor (e.g., a weight sensor, an infrared sensor, or a camera) may be disposed on or around each receiving conveyor 31, and the cost calculator 42 may obtain the held-article number Nf of each candidate receiving conveyor based on a detection result from the load sensor.

In addition, the number of articles A (hereafter referred to as a reserved-article number Nr) that are not currently held by a candidate receiving conveyor, but are determined to be shortly transported to the candidate receiving conveyor may also be different for each candidate receiving conveyor. In the example in FIG. 5, one article A is already determined to be newly transported to the candidate receiving conveyor on the left, and the reserved-article number Nr is 1. In contrast, no article A is currently scheduled to be newly transported to the candidate receiving conveyor on the right, and the reserved-article number Nr is 0. In FIG. 5, the article A hatched with dashed lines represents the article A that is scheduled to be transported later.

The cost calculator 42 can obtain the reserved-article number Nr of each candidate receiving conveyor based on information about the goal of each article transport vehicle 10 that is tracked by the host controller 41.

The cost calculator 42 calculates, for each candidate receiving conveyor, a receivable-article number Ne (Ne=Nx−Nf−Nr) by subtracting the held-article number Nf and the reserved-article number Nr from the maximum holdable-article number Nx. The receivable-article number Ne represents a net margin, or specifically, the number of articles currently not held by the candidate receiving conveyor and currently not reserved for the candidate receiving conveyor. In the example in FIG. 5, the receivable-article number Ne of the candidate receiving conveyor on the left is 2, which is obtained by subtracting 2 as the held-article number Nf and 1 as the reserved-article number Nr from 5 as the maximum holdable-article number Nx. In contrast, the receivable-article number Ne of the candidate receiving conveyor on the right is 1 obtained by subtracting 4 as the held-article number Nf and 0 as the reserved-article number Nr from 5 as the maximum holdable-article number Nx.

The cost calculator 42 then calculates the receiving cost for each candidate receiving conveyor based on the receivable-article number Ne. In the present embodiment, the receiving cost increases when the receivable-article number Ne decreases. In other words, the receiving cost decreases when the receivable-article number Ne increases. In the example in FIG. 5, the receiving cost of the candidate receiving conveyor on the left is lower than the receiving cost of the candidate receiving conveyor on the right.

The destination determiner 43 determines a receiving conveyor 31 to be an actual destination of the article A among the multiple candidate receiving conveyors based on the path costs and the receiving costs calculated by the cost calculator 42 (step #04 in FIG. 6). The destination determiner 43 sums the path cost and the receiving cost of each candidate receiving conveyor and determines the candidate receiving conveyor with the lowest total cost as the receiving conveyor 31 to be the destination.

The total cost may be calculated by simply adding the path cost and the receiving cost or by adding the path cost and the receiving cost weighted in a predetermined manner. In the latter case, coefficients may be set based on the requirement specification of the article transport facility 1. To prioritize the transport efficiency with a shorter travel time of the article transport vehicle 10 to the receiving conveyor 31 as the destination, for example, the path cost may be adjusted to have a relatively larger coefficient than the receiving cost. To prioritize the leveling of a load on each of the multiple receiving conveyors 31 to avoid specific receiving conveyors 31 intensively receiving the load, for example, the receiving cost may be adjusted to have a relatively larger coefficient than the path cost.

### Other Embodiments

(1) In the above embodiment, each receiving conveyor 31 includes one receiving area 32 and one transfer area 36. In some embodiments, as shown in, for example, FIG. 7, the structure may include, as the receiving conveyor 31 of another type, a multi-receiving conveyor 31M including multiple (two in the example in FIG. 7) receiving areas 32. The multi-receiving conveyor 31M described above can be used to receive articles A from a transport path 9A and a transport path 9B when, for example, the transport path 9 branches into the first transport path 9A and the second transport path 9B. The multi-receiving conveyor 31M includes a first receiving area 32A to receive an article A from an article transport vehicle 10 traveling along the first transport path 9A, a second receiving area 32B to receive an article A from an article transport vehicle 10 traveling along the second transport path 9B, and the shared transfer area 36 to transfer the received articles A to the storage unit 20. The multi-receiving conveyor 31M includes a first waiting area 34A between the first receiving area 32A and the transfer area 36 and second waiting areas 34B between the second receiving area 32B and the first receiving area 32A.

For the multi-receiving conveyor 31M described above, the maximum holdable-article number Nx is set for each of the multiple receiving areas 32 (in other words, individually for the first receiving area 32A and the second receiving area 32B). In the example in the figure, the maximum holdable-article number Nx of the first receiving area 32A is determined based on the total number of first receiving area 32A, first waiting area 34A, and transfer area 36, and the maximum holdable-article number Nx of the second receiving area 32B is determined based on the total number of second receiving area 32B and second waiting areas 34B. Thus, in this example, the maximum holdable-article number Nx is 3 for both the first receiving area 32A and the second receiving area 32B.

(2) In the above embodiment, the receiving conveyors 31 or the transfer conveyors 38 transport the articles A unidirectionally. In some embodiments, the receiving conveyors 31 or the transfer conveyors 38 may transport the articles A bidirectionally. In this case, each receiving conveyor 31 may include the waiting areas 34 adjacent to both ends of the receiving area 32.

(3) In the above embodiment, the multilayer storage shelf 21 in each storage unit 20 includes the storage shelf that is a tower. In some embodiments, for example, the multilayer storage shelf 21 may include a storage shelf that is a rack. In this case, the transport vehicles may move reciprocally between layers in the storage shelf. The storage units 20 may be automated warehouses including a stacker crane.

(4) In the above embodiment, the articles A transported by the article transport vehicles 10 are FOUPs that contain semiconductor wafers. In some embodiments, the articles A to be transported may be any articles such as reticle pods or open cassettes.

(5) The structure described in each of the above embodiments (including the above embodiments and other embodiments; the same applies hereafter) may be combined with any other structures described in the other embodiments unless any contradiction arises. The embodiments described herein are merely illustrative in all respects and may be modified as appropriate without departing from the spirit and scope of the disclosure.

### Overview of Embodiment

The article transport facility according to one or more embodiments of the disclosure may have the structure described below.

An article transport facility includes an article transport vehicle that moves along a transport path to transport an article, a control system that controls the article transport vehicle, and a plurality of receiving conveyors each to be a destination of the article transported by the article transport vehicle. Each of the plurality of receiving conveyors can hold less than or equal to a predetermined maximum holdable-article number of articles. The control system calculates, for each of the plurality of receiving conveyors, a receivable-article number by subtracting a held-article number and a reserved-article number from the maximum holdable-article number. The held-article number is a number of articles held by each of the plurality of receiving conveyors. The reserved-article number is a number of articles determined to be transported to each of the plurality of receiving conveyors. The control system selects, among the plurality of receiving conveyors, a receiving conveyor to be the destination of the article based on the receivable-article number of each of the plurality of receiving conveyors.

In this structure, the receiving conveyor to be the destination of the article is selected based on the receivable-article number (in other words, a margin to the maximum holdable-article number based on the sum of the actual held-article number and the reserved-article number) calculated for each of the plurality of receiving conveyors. This reduces the likelihood that the article transport vehicle reaches the receiving conveyor to be the destination but is to wait until the receiving conveyor is ready to actually receive the article. The article transport facility thus has the article transport efficiency less likely to decrease in the entire facility.

In one aspect, the control system may include a cost calculator that calculates a cost of transporting the article by the article transport vehicle. For each of the plurality of receiving conveyors, the cost calculator may calculate a lower cost at least in response to a shorter travel distance of the article transport vehicle to the receiving conveyor, and optionally in response to the receivable-article number of the receiving conveyor being greater.

In this structure, a receiving conveyor with a shorter travel distance to the article transport vehicle or a receiving conveyor with a greater margin to the maximum number of holdable articles is more likely to be selected as the destination of the article. This reduces the travel time of the article transport vehicle to the receiving conveyor as the destination to improve the article transport efficiency, and also allows the load on each of the plurality of receiving conveyors to be leveled.

In one aspect, the control system may select, among the plurality of receiving conveyors functionally equivalent to one another, the receiving conveyor to be the destination of the article.

In this structure, when one of the plurality of receiving conveyors that are functionally equivalent to one another can be selected to transport the article to its goal, an appropriate destination can be selected among the plurality of receiving conveyors. This improves the article transport efficiency and allows the article to be transported appropriately.

In one aspect, each of the plurality of receiving conveyors may include a receiving area to receive the article from the article transport vehicle and a transfer area to transfer the received article to a device other than the article transport vehicle. The plurality of receiving conveyors may include a multi-receiving conveyor including a plurality of the receiving areas. The multi-receiving conveyor has the maximum holdable-article number being set for each of the plurality of receiving areas.

In this structure, when the plurality of receiving conveyors in the article transport facility include the multi-receiving conveyor including the plurality of receiving areas, each of the plurality of receiving area can be a candidate for selection as a separate destination for which the maximum holdable-article number is set. This extends the range of selection for the destination compared with the actual number of receiving conveyors.

The article transport facility according to one or more embodiments of the disclosure produces at least one of the effects described above.

What is claimed is:

1. An article transport facility, comprising:
an article transport vehicle configured to move along a transport path to transport an article;
a control system configured to control the article transport vehicle; and
a plurality of receiving conveyors each to be a destination of the article transported by the article transport vehicle, and
wherein:
each of the plurality of receiving conveyors is configured to hold less than or equal to a predetermined maximum holdable-article number of articles,
the control system is configured to calculate, for each of the plurality of receiving conveyors, a receivable-article number by subtracting a held-article number and a reserved-article number from the maximum holdable-article number, the held-article number is a number of articles held by each of the plurality of receiving conveyors, the reserved-article number is a number of articles determined to be transported to each of the plurality of receiving conveyors,
the control system is configured to select, among the plurality of receiving conveyors, a receiving conveyor to be the destination of the article based on the receivable-article number of each of the plurality of receiving conveyors.

2. The article transport facility according to claim 1, wherein:
the control system comprises a cost calculator configured to calculate a cost of transporting the article by the article transport vehicle, and
for each of the plurality of receiving conveyors, the cost calculator calculates a lower cost at least in response to a shorter travel distance of the article transport vehicle to the receiving conveyor, and in response to the receivable-article number of the receiving conveyor being greater.

3. The article transport facility according to claim 1, wherein:
each of the plurality of receiving conveyors comprises a receiving area to receive the article from the article transport vehicle and a transfer area to transfer the received article to a device other than the article transport vehicle,
the plurality of receiving conveyors comprise a multi-receiving conveyor comprising a plurality of the receiving areas, and
the multi-receiving conveyor has the maximum holdable-article number being set for each of the plurality of receiving areas.
